(19) United States
(12) Patent Application Publication
(10) Pub. No.: US 2011/0254605 A1
(43) Pub. Date: Oct. 20, 2011

(54) HIGH SPEED DUAL MODULUS PRESCALER

(76) Inventors: Jin-Fa Lin, Chiayi County (TW); Yin-Tsung Hwang, Taichung City (TW); Ming-Hwa Sheu, Yunlin County (TW)

(21) Appl. No.: 12/759,931

(22) Filed: Apr. 14, 2010

(51) Int. Cl. H03K 3/00

(52) U.S. Cl. 327/218

(57) ABSTRACT

A high speed dual modulus prescaler aims to be used on a frequency synthesizer of wireless communication systems to divide frequency of input signals. The high speed dual modulus prescaler includes a first D flip-flop, a second D flip-flop and a main control transistor. The main control transistor switches connection of the first D flip-flop and second D flip-flop. The main control transistor provides an OR gate state and an AND gate state to form an OR gate circuit and an AND gate circuit in the prescaler. Thereby the number of transistors in the prescaler can be reduced to increase operation speed and lower power consumption.

### FIELD OF THE INVENTION

The present invention relates to a prescaler and particularly to a high speed dual modulus prescaler for use in a frequency synthesizer of wireless communication systems.

### BACKGROUND OF THE INVENTION

In a wireless communication system prescaler is a necessary element in system frequency planning, especially in high frequency modules. To shrink circuit size and reduce power consumption, and to satisfy the requirement for a high speed modulus prescaler become a high priority research and development issue in the industry.

In a frequency synthesizer that adopts the design of a phase-locked loop (PLL) the high speed dual modulus prescaler is one of the most important critical circuits. This is mainly because its circuit operating in a very high frequency and consuming most power.

In conventional techniques the prescaler usually includes two D flip-flops incorporating with a NOR gate and a NAND gate between both D flip-flops. Reference of the conventional D flip-flop can be found in a circuit disclosed by Yuan, J and Svensson, C in “High-speed CMOS circuit technique” at IEEE J. Solid-State Circuit, Vol. 24, pp. 62-70, February 1989. Referring to FIG. 1, it provides a true single phase clock D flip-flop (TSPC D flip-flop in short) consisting of nine transistors. While the D flip-flop thus formed can be used in a high speed circuit, its transistors are numerous that result in a great amount of power consumption. This problem is yet to be resolved.

J. Navarro and W. Van Noije proposed “A 1.6-GHz dual modulus prescaler using the Extended True-Single-Phase-Clock CMOS circuit technique (E-TSPC)” at IEEE J. Solid-State Circuits, vol. 34, pp. 97-102, Jan. 1999. It is an extended TSPC D flip-flop (E-TSPC D flip-flop in short). Referring to FIG. 2, it employs fewer transistors in the circuit, eventually six pieces of transistors are used Compared to conventional TSPC designs, the E-TSPC design removes the transistor stacked structure and all the transistors are free of the body effect. The E-TSPC design is thus more sustainable for high operating frequency operations in the face of low voltage supply.

On the prescaler, to achieve high speed frequency division and reduce power consumption generally adopts an approach of high speed frequency division (such as dividing the signal by 4), then performs a high rate frequency division of the signal gone through the previous high speed frequency division (such as dividing the previously divided signal by 32), then a dual modulus prescaler with frequency division of 128 is attained. The prescaler thus consumes less power and has a faster process speed. However, coupling the prescaler with separated NOR gate and NAND gate needs a greater number of transistors. Hence it is not a desirable circuit design. To solve this problem, S. Pellerano, S. Levantino, C. Samori and A. L. Lacaita disclosed a prescaler containing fewer transistors in “A 13.5-mW 5-GHz frequency synthesizer with dynamic-logic frequency divider,” at IEEE J. Solid-State Circuits, vol. 39, no. 2, pp. 378-383, February 2004. Referring to FIG. 3, the prescaler includes an OR gate transistor Mor coupling in parallel with a first N-transistor in a first D flip-flop 1 to form a gate circuit, and an AND gate transistor Mad coupling in parallel with a fourth P-transistor p4 in a second D flip-flop 2 to form an AND gate circuit, and an inverter 3 to perform invert process. Total sixteen transistors are used to form a prescaler function with division by two or three. The parallel OR gate transistor Mor and the first N-transistor n1, and the AND gate transistor Mad and fourth P-transistor p4 can prevent the problem of low speed charging and discharging happened to that circuits coupled in series.

The aforesaid reference sets the second D flip-flop 2 ON/OFF through the inverter 3 to perform the process of division by two or three. When output of the inverter 3 is 1, the fourth P-transistor p4 is OFF and closes the second D-flip-flop 2. The first D flip-flop 1 is only used as a prescaler to divide the frequency by two. When output of the inverter 3 is 0, the fourth P-transistor p4 is ON and make the first D flip-flop 1 and second D-flip-flop 2 connect to each other, then a prescaler to divide the frequency by three is formed.

According to the aforesaid reference, ON/OFF of the second D flip-flop 2 is controlled by an output signal of the inverter 3. But when the OR gate transistor Mor is ON and the input signal in is 0, a first P-transistor p1 electrically connected to the OR gate transistor Mor also is set ON. Power source directly connects to the ground through the first P-transistor p1 and OR gate transistor Mor. However, a DC short current power problem still takes place, so that power consumption increases.

### SUMMARY OF THE INVENTION

The primary object of the present invention is to solve the power consumption issue resulting from DC short current power problem occurred to the conventional techniques to save electric energy.

To achieve the foregoing object the present invention provides a high speed dual modulus prescaler to receive a clock signal. It includes a first D flip-flop, a second D flip-flop and a main control transistor. The first D flip-flop includes a first output end and a first clock input end. The clock signal is sent to the first D flip-flop through the first clock input end. The second D flip-flop includes a second data input end and a second clock input end. The clock signal is sent to the second D flip-flop through the second clock input end. The main control transistor includes a drain, a source and a gate. The drain is connected to the first output end. The source is connected to the second data input end.

By means of the structure set forth above, the first D flip-flop and the second D flip-flop are connected through the main control transistor, and the main control transistor provides an OR gate state and an AND gate state. At the OR gate state the main control transistor and the circuit in the first D flip-flop form an OR gate circuit to displace the OR gate transistor in the conventional techniques. At the AND gate state the main control transistor and the circuit in the second D flip-flop form an AND gate circuit to displace the AND gate circuit in the conventional techniques. Thus the number of transistors in the prescaler can be reduced.

The foregoing, as well as additional objects, features and advantages of the present invention will be more readily apparent from the following detailed description, which proceeds with reference to the accompanying drawings.

### BRIEF DESCRIPTION OF THE DRAWINGS

FIG. 1 is a schematic view of a conventional TSPC D flip-flop.

FIG. 2 is a schematic view of a conventional E-TSPC D flip-flop.

FIG. 3 is a circuit diagram of a conventional prescaler.

FIG. 4 is a circuit diagram of an embodiment of the present invention.

FIG. 5 is a circuit waveform chart of simulation results of an embodiment of the present invention.

FIG. 6 is a comparison chart showing power consumption simulation results of the present invention and a conventional technique.

FIG. 7 is a comparison chart showing power delay product of simulation results of the present invention and a conventional technique.

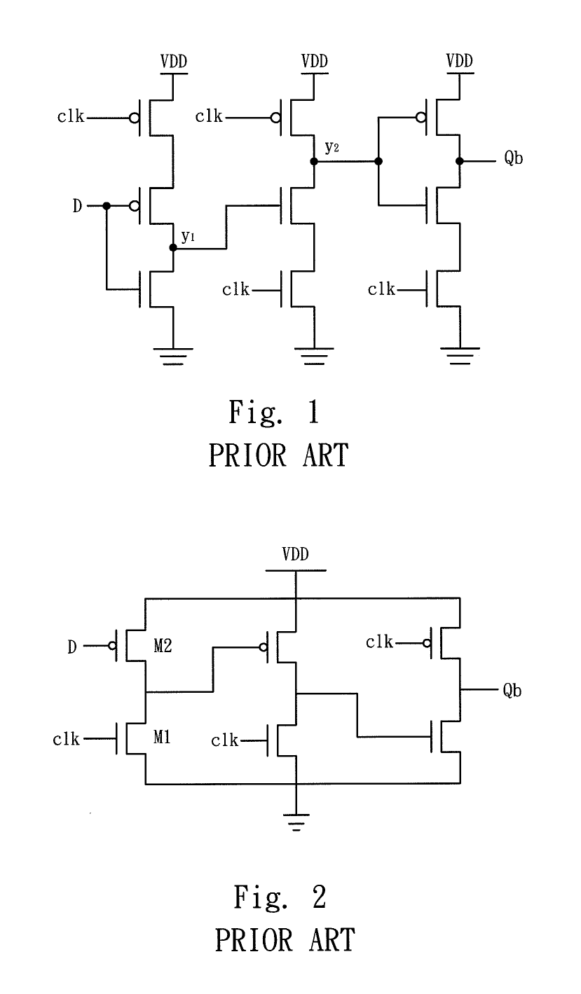

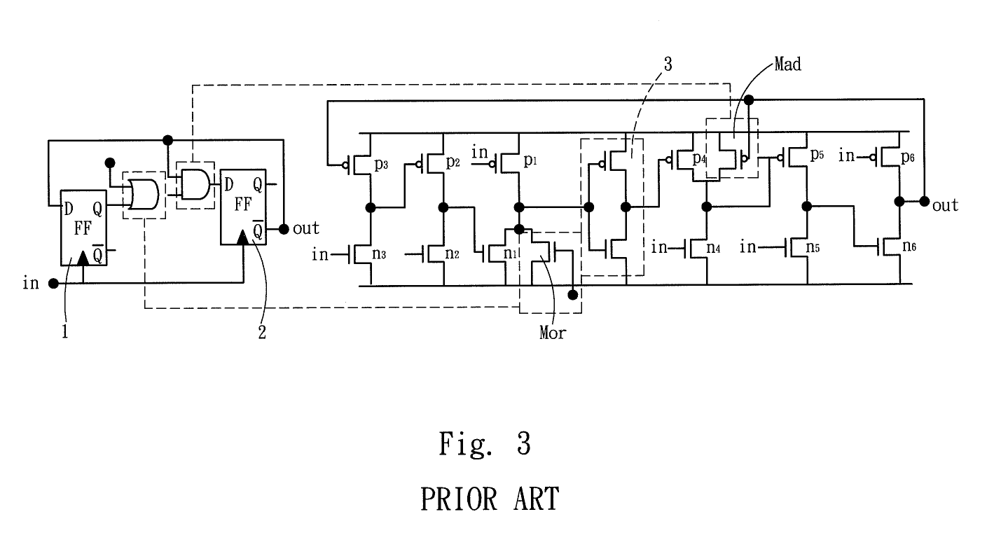

### DETAILED DESCRIPTION OF THE PREFERRED EMBODIMENT

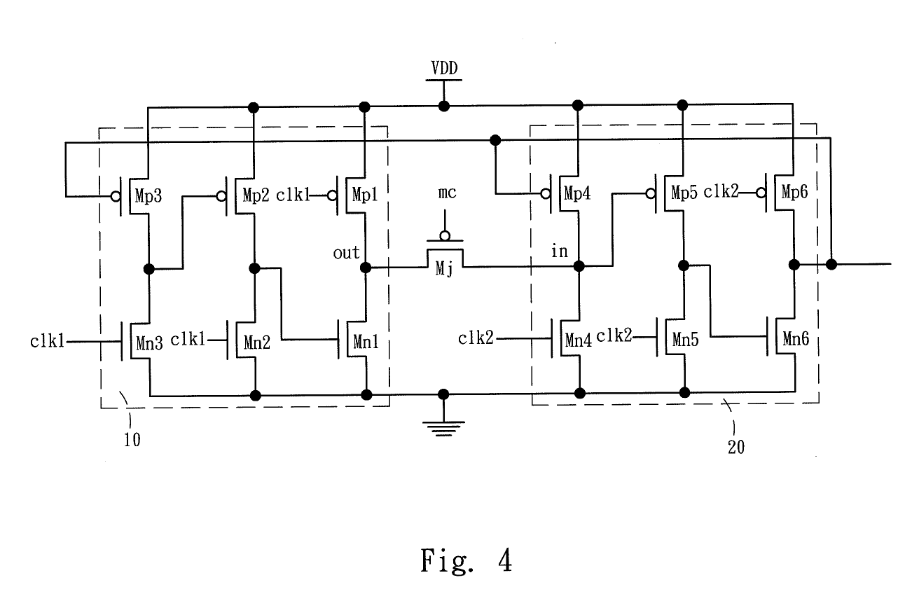

Please refer to FIG. 4 for a circuit diagram of an embodiment of the present invention. The high speed dual modulus prescaler according to the present invention aims to receive a clock signal. The high speed dual modulus prescaler includes a first D flip-flop 10, a second D flip-flop 20 and a main control transistor Mj. The first D flip-flop 10 includes a first output end out and a first clock input end clk1. The clock signal is sent to the first D flip-flop 10 through the first clock input end clk1. The second D flip-flop 20 includes a second data input end in and a second clock input end clk2. The clock signal is sent to the second D flip-flop 20 through the second clock input end clk2. The main control transistor Mj includes a drain, a source and a gate. The drain is connected to the first output end out. The source is connected to the second data input end in. In this embodiment the main control transistor Mj is a P-transistor with the gate to receive a mode control signal mc. Through the mode control signal mc the main control transistor mj controls connection between the first D flip-flop 10 and second D flip-flop 20 to change mode states. In this embodiment the mode states include mode 2 and mode 3. At mode 2 the frequency of the clock signal is divided by two. At mode 3 the frequency of the clock signal is divided by three.

More specifically, the first D flip-flop 10 includes a first N-transistor Mn1, a second N-transistor Mn2, a third N-transistor Mn3, a first P-transistor Mp1, a second P-transistor Mp2 and a third P-transistor Mp3. Each of the N transistors and P transistors includes a drain, a source and a gate. The source of the first P-transistor Mp1 is connected to the drain of the first N-transistor Mn1 to form the first output end out; the source of the second P-transistor Mp2 is connected to the drain of the second N-transistor Mn2, and the source of the third P-transistor Mp3 is connected to the drain of the third N-transistor Mn3. The gates of the second N-transistor Mn2, third N-transistor Mn3 and first P-transistor Mp1 all serve as the first clock input end clk1 to receive the clock signal.

The second D flip-flop 20 includes a fourth N-transistor Mn4, a fifth N-transistor Mn5, a sixth N-transistor Mn6, a fourth P-transistor Mp4, a fifth P-transistor Mp5 and a sixth P-transistor Mp6. Each of the N transistors and P transistors includes a drain, a source and a gate. The source of the fourth P-transistor Mp4 is connected to the drain of the fourth N-transistor Mn4 to form the second data input end in; the source of the fifth P-transistor Mp5 is connected to the drain of the fifth N-transistor Mn5, and the source of the sixth P-transistor Mp6 is connected to the drain of the sixth N-transistor Mn6. The gates of the fourth N-transistor Mn4, fifth N-transistor Mn5 and sixth P-transistor Mp6 all serve as the second clock input end clk2 to receive the clock signal

The main control transistor Mj has an OR gate state and an AND gate state. During the OR gate state the main control transistor Mj is coupled in parallel with the first N-transistor Mn1 to form an OR gate circuit. At the AND gate state the main control transistor Mj is coupled in parallel with the fourth P-transistor Mp4 to form an AND gate circuit. Moreover, the gate of the main control transistor Mj receives a control signal to control connection of the first D flip-flop 10 and second D flip-flop 20.

In addition, the first P-transistor Mp1 is set ON when the clock signal is 0, and the main control transistor Mj also is set ON; the fourth N-transistor Mn4 is OFF when the clock signal is 0, thus DC shot current power problem does not occur.

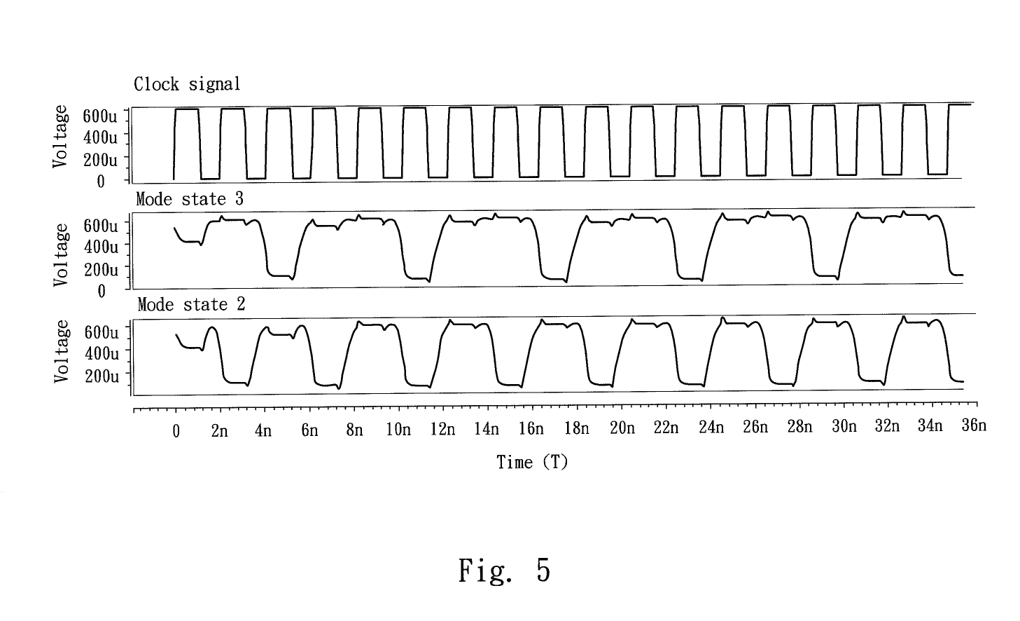

Refer to FIG. 5 for a circuit waveform chart of simulation results of an embodiment of the present invention. The upper transverse chart shows the clock signal waveforms. The middle transverse chart shows the mode 3 state after the frequency has been divided by three according to the present invention. The lower transverse chart shows the mode 2 state after the frequency has been divided by two according to the present invention. As indicated in the charts, the prescaler of the present invention can divide the input clock signal by two or three and maintain a constant voltage value.

Please refer to Table 1 below for comparison results of the present invention and a conventional techniques based on TSMC (Taiwan Semiconductor Manufacturing Company) 0.18 μm manufacturing process:

TABLE 1
Result comparison of the present invention and a
conventional technique

| Precaler circuit | Conventional | The present |
|---|---|---|
| designs | technique | Invention |
| Transistor number | 16/4 | 13/1 |
| Maximum use | 497/445 | 502/497 |
| frequency (MHz) | | |
| Power consumption | 6.38/5.97 | 5.24/5.27 |
| (μW) | | |
| Power saving ratio | | 23%/27% |

It is to be noted that the conventional technique adopts the one disclosed in “A 13.5-mW 5-GHz frequency synthesizer with dynamic-logic frequency divider” proposed by S. Pellerano, S. Levantino, C. Samori and A. L. Lacaita at IEEE J. Solid-State Circuits, vol. 39, no. 2, pp. 378-383, February 2004. The conventional technique uses 16 transistors, among them 12 transistors are used on two D flip-flops. Extra four transistors are deployed. The present invention employs total 13 transistors, with only one extra transistor. The maximum frequencies used by the conventional techniques are 497 MHz and 445 MHz for mode 2 and mode 3, but 502 MHz and 497 MHz for mode 2 and mode 3 in the present invention. On power consumption, the conventional techniques are 6.38 μW and 5.97 μW for mode 2 and mode 3, but only 5.24 μW and 5.27 μW for mode 2 and mode 3 in the present invention. Thus the present invention can save up to 23% and 27% of power at mode 2 and mode 3.

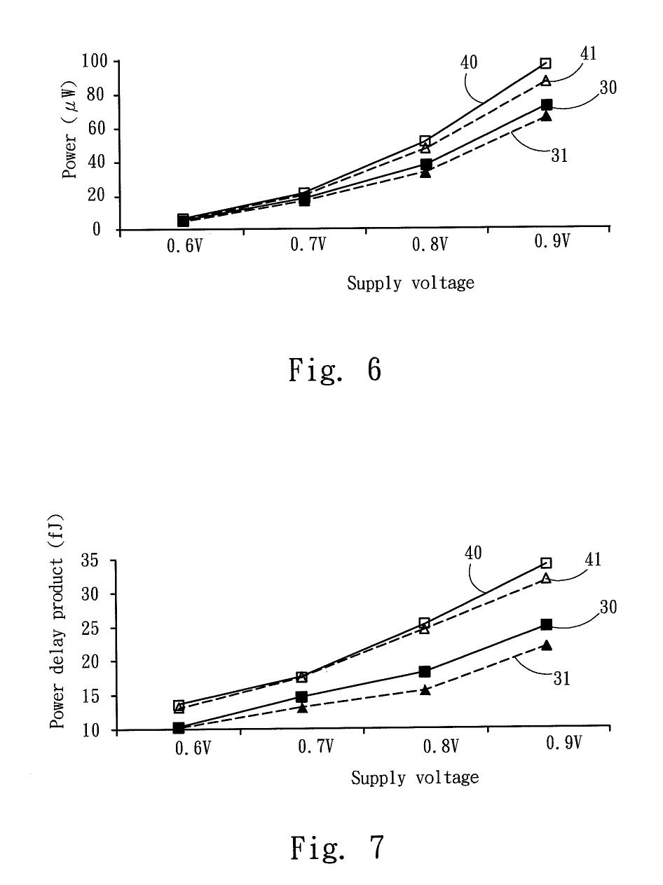

Please refer to FIG. 6 for the comparison chart of power consumption of simulation results of the present invention and a conventional technique. Given a same voltage the power consumption of the present invention at mode 2 (line 30) and mode 3 (line 31) is smaller than the conventional technique at mode 2 (line 40) and mode 3 (line 41). Also refer to FIG. 7 for comparison chart of power delay product of simulation results of the present invention and a conventional technique. It clearly indicates that the present invention provides a significant improvement over the conventional technique in terms of high frequency, lower frequency and power consumption both at mode 2 (line 30) and mode 3 (line 31).

As a conclusion, compared with the conventional techniques, the present invention provides the following features and advantages:

1. The first D flip-flop 10 and second D flip-flop 20 are connected through the main control transistor Mj, and the gate of the main control transistor Mj receives a control signal to switch connection ON/OFF of the first D flip-flop 10 and second D flip-flop 20 to displace the conventional techniques of setting OFF the fourth P-transistor Mp4 to break connection of the first D flip-flop 10 and second D flip-flop 20.

2. The main control transistor Mj provides an OR gate state and an AND gate state to displace the OR gate transistor and AND gate transistor in the conventional techniques, so that the number of transistors and power consumption can be reduced.

3. Existing of the main control transistor Mj also overcomes the DC shot current power problem occurred to the conventional circuits.

In summation of the above description, the present invention provides a significant improvement over the conventional techniques and complies with the patent application requirements, and is submitted for review and granting of the commensurate patent rights.

While the preferred embodiment of the present invention has been set forth for the purpose of disclosure, modifications of the disclosed embodiment of the present invention as well as other embodiments thereof may occur to those skilled in the art. Accordingly, the appended claims are intended to cover all embodiments which do not depart from the spirit and scope of the present invention.

1. A high speed dual modulus prescaler to receive a clock signal, comprising:
a first D flip-flop which includes a first output end and a first clock input end, the clock signal being sent to the first D flip-flop through the first clock input end;
a second D flip-flop which includes a second data input end and a second clock input end, the clock signal being sent to the second D flip-flop through the second clock input end; and
a main control transistor which include a drain, a source and a gate, the drain being connected to the first output end, the source being connected to the second data input end.

2. The high speed dual modulus prescaler of claim 1, wherein the first D flip-flop includes a first N-transistor, a second N-transistor, a third N-transistor, a first P-transistor, a second P-transistor and a third P-transistor, each of the N transistors and P transistors including a drain, a source and a gate, the source of the first P-transistor being connected to the drain of the first N-transistor, the source of the second P-transistor being connected to the drain of the second N-transistor, and the source of the third P-transistor being connected to the drain of the third N-transistor.

3. The high speed dual modulus prescaler of claim 1, wherein the second D flip-flop includes a fourth N-transistor, a fifth N-transistor, a sixth N-transistor, a fourth P-transistor, a fifth P-transistor and a sixth P-transistor; each of the N transistors and P transistors include a drain, a source and a gate, the source of the fourth P-transistor being connected to the drain of the fourth N-transistor, the source of the fifth P-transistor being connected to the drain of the fifth N-transistor, and the source of the sixth P-transistor being connected to the drain of the sixth N-transistor.

4. The high speed dual modulus prescaler of claim 1, wherein the main control transistor is a P-transistor.

5. The high speed dual modulus prescaler of claim 1, wherein the main control transistor is a single switch which alone receives a mode control signal.

6. The high speed dual modulus prescaler of claim 1, wherein the drain of the main control transistor is directly connected to the first output end and the source of the main control transistor is directly connected to the second date input end.
